(19) United States
(12) Patent Application Publication
(10) Pub. No.: US 2019/0249294 A1
(43) Pub. Date: Aug. 15, 2019

(54) CARRIER FOR HOLDING A SUBSTRATE, USE OF THE CARRIER IN A PROCESSING SYSTEM, PROCESSING SYSTEM EMPLOYING THE CARRIER, AND METHOD FOR CONTROLLING A TEMPERATURE OF A SUBSTRATE

(71) Applicant: Applied Materials, Inc., Santa Clara, CA (US)

(72) Inventors: Simon LAU, Alzenau (DE); Gerhard WOLF, Büdingen (DE); Reiner HINTERSCHUSTER, Hammersbach (DE); Thomas Werner ZILBAUER, Gauting (DE)

(21) Appl. No.: 15/766,338

(22) PCT Filed: Nov. 7, 2016
(86) PCT No.: PCT/EP2016/076830

§ 371 Date: Apr. 5, 2018

(51) Int. Cl. C23C 14/50; C23C 14/54; C23C 16/458; C23C 16/46; H01L 21/67; H01L 21/683

(52) U.S. Cl. CPC C23C 14/50; C23C 14/541; H01L 21/683; C23C 16/466; H01L 21/67109; C23C 16/4586

(57) ABSTRACT

A carrier for holding a substrate is described. The carrier includes a carrier body having a first surface, and an adhesive arrangement provided on the first surface. The carrier body includes one or more conduits configured for providing a gas into the adhesive arrangement. Further, a method for controlling a temperature of a substrate is described. The method includes providing a carrier as described herein; supplying a gas through the one or more conduits into the adhesive arrangement; and providing the gas to a backside of the substrate attached to the adhesive arrangement.

### TECHNICAL FIELD

Embodiments of the present disclosure relate to a carrier for holding a substrate, a deposition system for depositing material on a substrate, and a method for controlling a temperature of a substrate. Embodiments of the present disclosure particularly relate to a carrier for holding a substrate in a vacuum processing chamber, a vacuum processing system including a vacuum processing chamber, and a method for controlling a temperature of a substrate during substrate processing in a vacuum processing chamber.

### BACKGROUND

Techniques for layer deposition on a substrate include, for example, thermal evaporation, chemical vapor deposition (CVD) and physical vapor deposition (PVD) such as sputtering deposition. A sputter deposition process can be used to deposit a material layer on the substrate, such as a layer of an insulating material or a metal layer. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxinitride of the target material on the substrate.

Coated materials can be used in several applications and in several technical fields. For instance, coated materials may be used in the field of microelectronics, such as for generating semiconductor devices. Also, substrates for displays can be coated using a PVD process. Further applications include insulating panels, organic light emitting diode (OLED) panels, substrates with thin film transistors (TFTs), color filters or the like.

The tendency toward larger and also thinner substrates can result in bulging of the substrates due to stress applied to the substrate, e.g., during a deposition process. Support systems which hold a substrate during a deposition process introduce bulging on the substrate, e.g., due to forces that push the substrate edge towards the center of the substrate. Bulging can, in turn, cause problems due to the increasing likelihood of breakage. Accordingly, there is a need to reduce bulging and to support larger and thinner substrates without damage or breakage. Further, for some applications a thermal control of the substrate during substrate processing is desired, e.g. during material deposition in order to optimize the properties of the deposited layer on the substrate.

In light of the foregoing, there is a need to provide carriers for holding a substrate during substrate processing, processing systems, and methods for controlling process parameters, such as a temperature of a substrate during layer deposition, that overcome at least some of the problems in the art.

### SUMMARY

In light of the above, a carrier for holding a substrate, a processing system, and a method for controlling a temperature of a substrate are provided. Further aspects, benefits, and features of the present disclosure are apparent from the claims, the description, and the accompanying drawings.

According to an aspect of the present disclosure, a carrier for holding a substrate is provided. The carrier includes a carrier body having a first surface, and an adhesive arrangement provided on the first surface, wherein the carrier body includes one or more conduits configured for providing a gas into the adhesive arrangement.

According to another aspect of the present disclosure, a use of the carrier according to any embodiments described herein in a processing system, particularly in a vacuum deposition system for depositing material on a substrate, is provided.

According to yet another aspect of the present disclosure, a processing system is provided. The processing system includes a processing chamber; a processing device; and a carrier according to any embodiments described herein.

According to a further aspect of the present disclosure, a method for controlling a temperature of a substrate is provided. The method includes providing a carrier according to any embodiments described herein; supplying a gas through the one or more conduits into the adhesive arrangement; and providing the gas to a backside of the substrate attached to the adhesive arrangement.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic cross sectional view of a carrier for holding a substrate according to embodiments described herein;

FIG. 2 shows a schematic perspective view of a carrier for holding a substrate according to embodiments described herein;

FIG. 3 shows a schematic detailed view of a section of a carrier according to embodiments described herein as indicated in FIG. 2;

FIG. 4A shows a schematic sectional view along the line A-A of the carrier as shown in FIG. 2;

FIG. 4B shows a schematic sectional view of carrier for holding a substrate according to further embodiments described herein;

FIG. 5A shows a schematic view of a carrier for holding two or more substrates according to further embodiments described herein;

FIG. 5B shows a schematic view of the carrier shown in FIG. 5A without the substrates;

FIG. 6 shows a schematic view of a processing system according to embodiments described herein; and

FIG. 7 shows a flow chart illustrating a method for controlling a temperature of a substrate according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

Before various embodiments of the present disclosure are described in more detail, some aspects with respect to some terms used herein are explained.

In the present disclosure, a “carrier for holding a substrate” is to be understood as a carrier which is configured for holding a substrate as described herein, particularly a large area substrate as described herein. Typically, the substrate held or supported by a carrier as described herein includes a front surface and a back surface, wherein the front surface is a surface of the substrate being processed, for example on which a material layer is to be deposited. Typically, the carrier is configured such that the back surface of the substrate can be attached to the carrier, particularly to an adhesive arrangement of the carrier as described herein.

The term “substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate can be made from any material suitable for material deposition. For instance, the substrate can be made from a material selected from the group consisting of glass (for instance soda-lime glass, borosilicate glass etc.), metal, polymer, ceramic, compound materials, carbon fiber materials, mica or any other material or combination of materials which can be coated by a deposition process. For example, the substrate can have a thickness of 0.1 mm to 1.8 mm, such as 0.7 mm, 0.5 mm or 0.3 mm. In some implementations, the thickness of the substrate may be 50 μm or more and/or 700 μm or less. Handling of thin substrates with a thickness of only a few microns, e.g. 8 μm or more and 50 μm or less, may be challenging.

According to some embodiments, the substrate can be a “large area substrate” and may be used for display manufacturing. For instance, the substrate may be a glass or plastic substrate. For example, substrates as described herein shall embrace substrates which are typically used for an LCD (Liquid Crystal Display), a PDP (Plasma Display Panel), and the like. For instance, a “large area substrate” can have a main surface with an area of 0.5 m² or larger, particularly of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

In the present disclosure, a “carrier body” is to be understood as a body of the carrier which is configured for holding the substrate. For instance the carrier body can be a rigid body, such as a frame or a plate which is configured for holding a substrate as described herein. In particular, the carrier body as described herein can be configured to support a surface of the substrate, such as the back surface of the substrate.

In the present disclosure, an “adhesive arrangement” is to be understood as an arrangement which is configured for providing an adhesive force for attaching a substrate as described herein. In particular, the adhesive arrangement can be provided on or attached to the carrier body, such that a substrate as described herein can be held by the carrier body via the adhesive arrangement. More specifically, the adhesive arrangement as described herein may include a dry adhesive material as described herein, which can be configured for providing the adhesive force by van der Waals forces.

In the present disclosure, the expression “one or more conduits configured for providing a gas into the adhesive arrangement” is to be understood as at least one conduit which is provided in the carrier body in order to provide a gas flow into the adhesive arrangement as described herein. In particular, the one or more conduits can be arranged within the carrier body such that the one or more conduits provide a passage from a second side of the carrier body (e.g. a backside of the carrier body) to a first side of the carrier body (e.g. a front side of the carrier body). Typically, the adhesive arrangement is provided on the front side of the carrier body. Accordingly, a gas can be provided into the adhesive arrangement via the one or more conduits. For instance, the gas provided through the one or more conduits into the adhesive arrangement can be process gas used during processing of the substrate in a processing system. Typically, the temperature T of the gas provided into the adhesive arrangement is approximately room temperature, for example T≤30° C., particularly T≤25° C., more particularly T≤20° C.

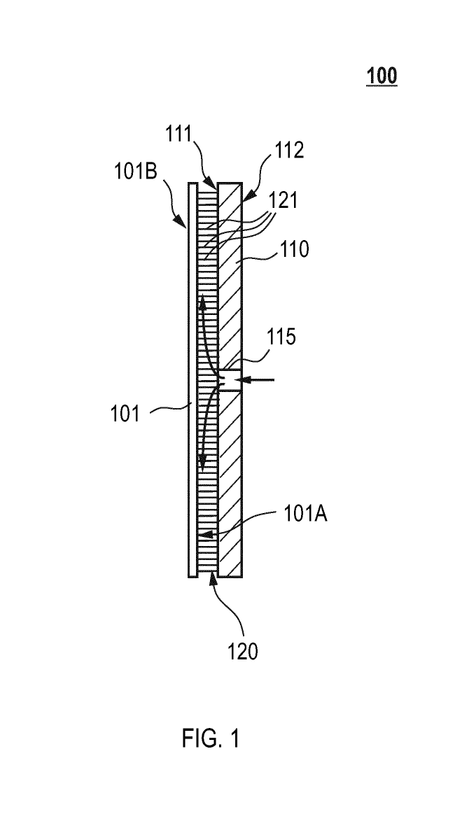

FIG. 1 shows a schematic side view of a carrier 100 for holding a substrate 101 according to embodiments described herein. The carrier 100 for holding the substrate 101 includes a carrier body 110 having a first surface 111, and an adhesive arrangement 120 provided on the first surface 111. Further, the carrier body 110 includes one or more conduits 115 configured for providing a gas into the adhesive arrangement 120.

Accordingly, a carrier according to embodiments described herein beneficially provides for a carrier with which a temperature of a substrate held by the carrier can be controlled. In particular, by providing a carrier which is configured such that a gas can be provided to a backside of a substrate held by an adhesive arrangement of the carrier, a simple and compact design of the carrier can be realized which can be used for controlling a temperature of the substrate during substrate processing.

For instance, as exemplarily shown in FIG. 1, embodiments of the carrier 100 as described herein provide for the possibility to provide a gas flow over a backside surface 101A of the substrate 101 such that a temperature of the substrate can be controlled, i.e. the temperature of the substrate can be limited to a particular preselected value. In other words, beneficially embodiments of the carrier as described herein are configured for providing a thermal control of a substrate, particularly by providing a convection of gas on the backside of the substrate held by the adhesive arrangement of the carrier. This can be beneficial for optimizing the properties of a layer deposited on a substrate, particularly a large area substrate, which is held by a carrier as described herein, since the substrate can be cooled. In other words, embodiments of the carrier as described herein beneficially provide for a canalized gas flow such that a proper convectional gas flow over the backside surface of the substrate held by the carrier can be provided under vacuum conditions, for instance in a vacuum processing chamber of a processing system as described herein.

With exemplary reference to FIG. 1, according to embodiments which can be combined with any other embodiments described herein, the adhesive arrangement 120 can be directly arranged on or attached to the first surface 111 of the carrier body 110. Typically, the adhesive arrangement 120 is configured for providing an adhesive force for holding the substrate 101. In particular, typically the adhesive force provided by the adhesive arrangement acts on a backside surface 101A of the substrate 101. Typically, the backside surface 101A of the substrate 101 is the substrate surface which is not processed. Accordingly, a compact design of a carrier for holding a substrate as described herein can be provided beneficially, while at the same time the carrier is configured such that a temperature of the substrate can be controlled.

As exemplarily indicated by the arrows in the adhesive arrangement 120 in FIG. 1, according to embodiments, which can be combined with any other embodiments described herein, the adhesive arrangement 120 is configured to be permeable to gas. Accordingly, beneficially a gas flow can be provided over the backside surface 101A of the substrate 101, such that the temperature of the substrate can be controlled by convection, such that a heat transfer from the substrate to the gas flowing over the backside surface of the substrate is achieved. For instance, the gas provided into the adhesive arrangement which flows over the backside surface of the substrate can have approximately room temperature. More specifically, the temperature T of the gas provided into the adhesive arrangement can be T≤30° C., particularly T≤25° C., more particularly T≤20° C.

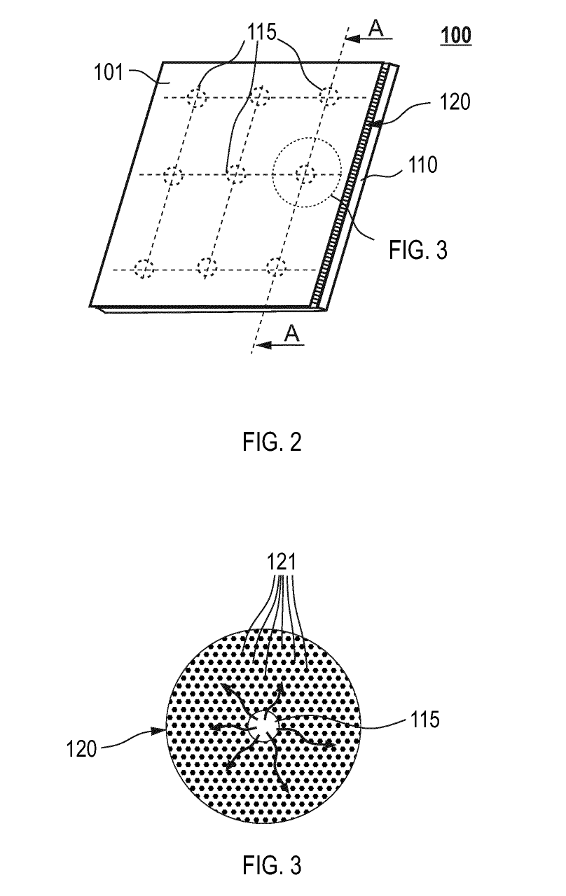

In FIG. 2 a schematic perspective view of a carrier for holding a substrate according to embodiments described herein is shown. With exemplary reference to FIG. 2, according to embodiments which can be combined with any other embodiments described herein the one or more conduits 115 may include a plurality of conduits which are arranged in the carrier body 110 of the carrier 100. In particular, the plurality of conduits can be distributed in the carrier body, particularly in a regular manner. In FIG. 2 the one or more conduits 115 are indicated as dotted circles. For instance, the plurality of conduits may be distributed throughout the carrier body 110. In particular, as exemplarily shown in FIG. 2, the plurality of conduits can be distributed throughout the carrier body in a regular manner. More specifically, the plurality of conduits can be distributed throughout the carrier body in a matrix-like manner, as exemplarily indicated by the dotted straight lines in FIG. 2. Although, nine conduits are indicated in the exemplary embodiment shown in FIG. 2, it is to be understood that any number of conduits in the carrier body can be provided, e.g. two or more, particularly four or more, more particularly ten or more. Further, alternatively the plurality of conduits may be distributed throughout the carrier body in a random manner.

In particular, according to embodiments which can be combined with any other embodiments described herein, the number of the plurality of conduits may be selected such that a sufficient gas flow over the backside surface of the substrate can be provided. More specifically, the plurality of conduits can be distributed in the carrier body such that a substantially homogeneous thermal control, particularly a substantially homogeneous cooling, of a substrate held by the adhesive arrangement can be realized. Accordingly, it is to be understood that the number of the plurality of conduits can be adapted to the size of the substrate which is to be held by the carrier as described herein.

According to embodiments which can be combined with any other embodiments described herein a lateral distance between neighboring conduits of the plurality of conduits may be 2.5 cm or more, particularly 5.0 cm or more, more particularly 7.5 cm or more, for instance 10 cm or more. According to embodiments which can be combined with any other embodiments described, the diameter D of the one or more conduits may be selected from a range between a lower limit of D=5 mm, particularly a lower limit of D=10 mm, more particularly a lower limit of D=15 mm and an upper limit of D=20 mm, more particularly an upper limit of D=25 mm, more particularly an upper limit of D=30 mm.

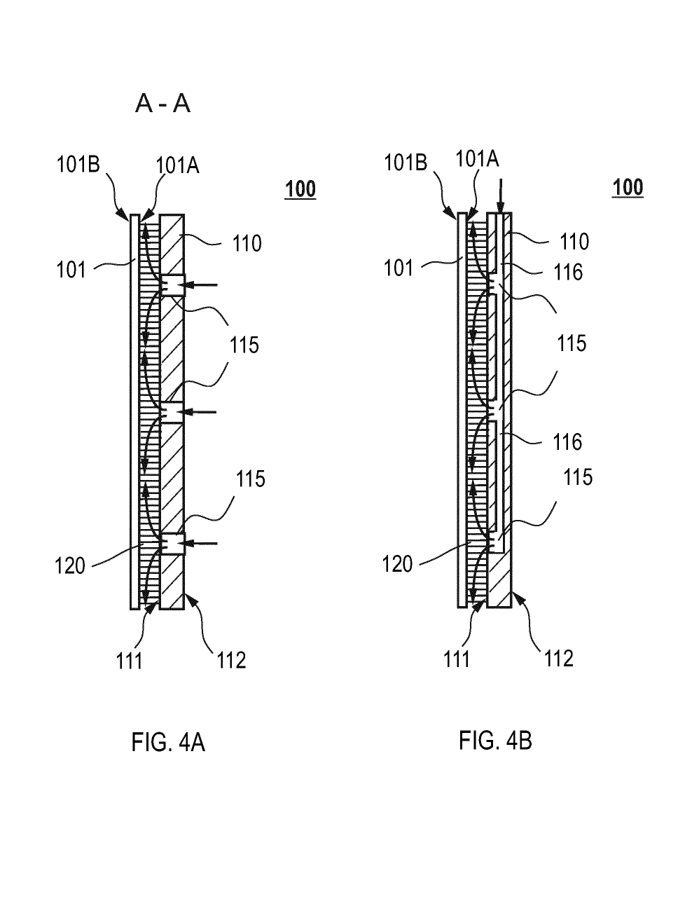

For illustration purposes, a schematic sectional view along the line A-A of the carrier as shown in FIG. 2 is shown in FIG. 4. In particular, FIG. 4 illustrates neighboring conduits through which a gas is provided into the adhesive arrangement 120 in order to provide a thermal control of the substrate attached to the adhesive arrangement. As indicated by the arrows located within the adhesive arrangement 120 shown in FIG. 4, the conduits are configured for providing a gas convection along the backside surface 101A of a substrate 101 attached to the adhesive arrangement 120.

In FIG. 3 a schematic detailed view of a section as indicated in FIG. 2 of a carrier described herein is shown. In particular, FIG. 2 shows a section of a top view on the adhesive arrangement 120 of the carrier. The section shown in FIG. 3 includes a conduit 115 as described herein. As indicated by the arrows extending from the conduit 115 into the adhesive arrangement 120, the adhesive arrangement 120 is configured to be permeable to gas. In particular, in the present disclosure the term “permeable to gas” can be understood in that a free path for a gas is provided in the adhesive arrangement. More specifically, the free pass for the gas in the adhesive arrangement can be provided such that a convection along a backside surface of a substrate attached to the adhesive arrangement can be provided. For instance, the adhesive arrangement can include a porous material having adhesive properties as described herein. More specifically, the adhesive arrangement 120 can include a plurality of filaments 121 which are arranged such that a permeable or porous configuration of the adhesive arrangement is provided. In other words, the structure of the adhesive arrangement can be configured to be porous or spongy in a way that the gas can reach the substrate and flow along the substrate surface for heat transfer. In particular, beneficially the adhesive arrangement is configured such that a gas provided into the adhesive arrangement can substantially reach the full backside surface of the substrate.

Accordingly, as exemplarily shown in FIGS. 1 and 3, according to embodiments, which can be combined with any other embodiments described herein, the adhesive arrangement 120 can include a plurality of filaments 121 (for illustration purpose only some filaments are marked by the reference sign) which can be attached to the carrier body 110 such that the plurality of filaments extend away from the first surface 111 of the carrier body 110. Such a configuration is in particular beneficial for providing the gas permeability of the adhesive arrangement as described herein.

As exemplarily shown in FIG. 1, each filament of the plurality of filaments 121 can be attached with one end to the first surface 111 of the carrier 100. In particular, each filament of the plurality of filaments 121 can extend away from the first surface 111 of the carrier 100, for instance perpendicular to first surface 111 of the carrier 100. Accordingly, each filament of the plurality of filaments 121 can have a second end that is free, for instance for an attachment of a substrate as described herein. In particular, the second end of each filament of the plurality of filaments 121 can be configured to be attachable to the substrate 101. Specifically, the second end of each filament can be configured to adhere to the substrate 101 by van der Waals forces as outlined herein.

For instance, the filaments can include or be nanotubes or carbon nanotubes. Each of the plurality of filaments can be a substantially longitudinal member. Specifically, each of the plurality of filaments can have one dimension that is larger than the remaining two dimensions. In particular, the longest dimension of the filaments can be the length of the filament. That is, the filaments can be elongated along a length direction.

According to embodiments, which can be combined with any other embodiments described herein, the adhesive arrangement 120 can include a dry adhesive material configured for attaching the substrate 101 to the carrier body 110. For instance, the dry adhesive material can be a synthetic setae material. The adhesive capabilities of the dry adhesive material, specifically of the synthetic setae material, can be related to the adhesive properties of a gecko foot. The natural adhesive capability of the gecko foot allows the animal to adhere to many types of surfaces under most conditions. The adhesive capability of the gecko foot is provided by numerous hair-type extensions, called setae, on the feet of the gecko. It is noted here that the term “synthetic setae material” can be understood as a synthetic material which emulates the natural adhesive capability of the gecko foot and which includes similar adhesive capabilities to the gecko foot. Moreover, the term “synthetic setae material” can be synonymously used with the term “synthetic gecko setae material” or with the term “gecko tape material”. For example, a carrier having a gecko adhesive material may also be referred to as G-chuck. However, the present disclosure is not limited thereto and other dry adhesive materials suitable for holding the substrate can be used.

According to embodiments, which can be combined with any other embodiments described herein, the dry adhesive material, for example the synthetic setae material, can be inorganic. According to some embodiments described herein, the dry adhesive material can be substantially 100% inorganic. Moreover, the microstructure of the dry adhesive material can include nanotubes. According to some embodiments described herein, the microstructure of the dry adhesive material includes carbon nanotubes.

According to embodiments, which can be combined with any other embodiments described herein, the dry adhesive material can be a gecko adhesive. For example, the gecko adhesive may be a gecko tape or a gecko element.

In the context of the present disclosure, a “gecko adhesive” can be understood as an adhesive that mimics the ability of geckos' feet to adhere to surfaces, such as for example vertical surfaces. In particular, the dry adhesive material of the adhesive arrangement 120 as described herein can be configured to adhere to the substrate 101 due to van der Waals forces between the dry adhesive material and a surface of the substrate 101. However, the present disclosure is not limited thereto, and other adhesives suitable for holding the substrate can be used.

According to embodiments, which can be combined with any other embodiments described herein, the adhesive force provided by the dry adhesive material can be sufficient for holding a substrate as described herein. In particular, the dry adhesive material can be configured to provide an adhesive force of about 2 N/cm² or more, particularly 3 N/cm² or more, more particularly 4 N/cm² or more, for instance at least 5 N/cm².

With exemplary reference to FIGS. 1 and 4, according to embodiments, which can be combined with any other embodiments described herein, the one or more conduits 115 are configured to extend from a second surface 112 of the carrier body 110 to the first surface 111 of the carrier body 110, wherein the second surface 112 is opposed to the first surface 111. For instance, the first surface 111 of the carrier body 110 can be a front side of the carrier and the second surface 112 of the carrier body 110 can be a backside of the carrier. In other words, a conduit as described herein can be understood as a passage or a through-hole from the backside of the carrier to a front side of the carrier. Accordingly, the one or more conduits 115 can be configured to penetrate the carrier body 110. Specifically, the one or more conduits 115 can be configured to provide a fluid communication from a backside of the carrier to a front side of the carrier, particularly into the adhesive arrangement 120.

With exemplary reference to FIG. 4B, according to some embodiments, which can be combined with other embodiments described herein, the one or more conduits 115 can be connected to a gas supply conduit 116, which is configured to guide the gas through the carrier body 110 to the one or more conduits 115. For instance, the gas supply conduit 116 may be arranged within the carrier body 110. For instance, the gas supply conduit 116 can extend substantially parallel to the first surface 111 of the carrier body 110, exemplarily shown in FIG. 4B. Typically, the gas supply conduit 116 is configured such that the gas can be introduced into the gas supply conduit 116 from at least one side of the carrier body. For example, according to the exemplary implementation as shown in FIG. 4B, the gas supply conduit 116 can be arranged and configured such that the gas can be introduced into the gas supply conduit 116 from a top side surface of the carrier body. Additionally or alternatively, the gas supply conduit 116 can be arranged and configured such that the gas can be introduced into the gas supply conduit 116 from a bottom side surface of the carrier body (not explicitly shown). Accordingly, additionally or alternatively, the gas supply conduit 116 can also be arranged and configured such that the gas can be introduced into the gas supply conduit 116 from a left side surface and/or a right side of the carrier body (not explicitly shown).

According to embodiments, which can be combined with any other embodiments described herein, the adhesive arrangement 120 can be configured to have an attachment area which corresponds to at least 75% of the backside surface 101A of the substrate 101. In particular, the adhesive arrangement 120 can be configured to have an attachment area which corresponds to at least 80% of the backside surface 101A of the substrate 101, more particularly to at least 90% of the backside surface 101A of the substrate 101. In the present disclosure, an “attachment area” can be understood as an area of the adhesive arrangement which provides for a continuous area of adhesive material as described herein.

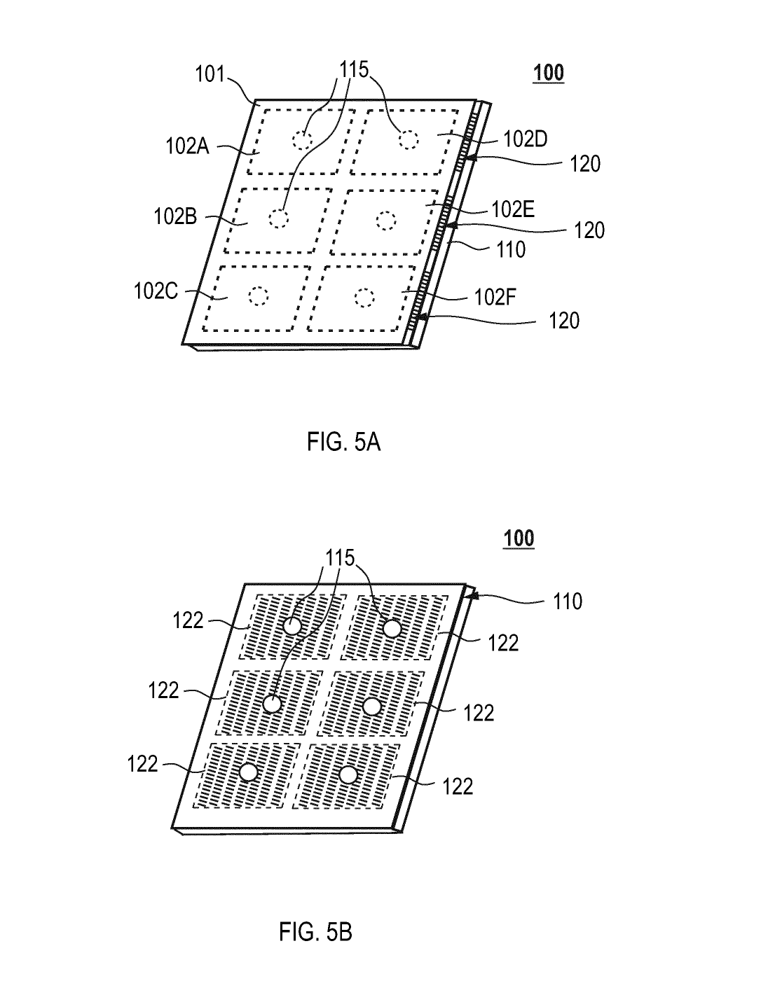

With exemplary reference to FIGS. 5A and 5B, according to some embodiments, which can be combined with other embodiments described herein, the adhesive arrangement 120 can be configured to have two or more attachment zones 122. Accordingly, the one or more conduits 115 can be configured such that each of the two or more attachment zones 122 can be provided with gas, as exemplarily shown in FIGS. 5A and 5B. In particular, the one or more conduits 115 can be arranged within the carrier body 110 such that a gas flow convection over the backside of the substrate attached to the two or more attachment zones 122 can be provided. In FIG. 5A, an exemplary embodiment of a carrier having six attachment zones is shown to which the substrate 101 is attached. Further, in FIG. 5A six areas are indicated (102A to 102F), which, for example, represent six devices (e.g. displays) which are cut from the substrate after processing, particularly after coating of the substrate. Accordingly, by providing a carrier with two or more attachment zones 122 with a size substantially corresponding to the size of the later individual devices cut form the substrate, less adhesive material is needed compared to a configuration in which the adhesive material of the adhesive arrangement is provided over substantially the complete substrate back surface, as exemplarily shown in FIGS. 1 and 2. For illustration purpose, in FIG. 5B a schematic view of the carrier of FIG. 5A is shown without the substrates.

In some implementations, as exemplarily shown in FIG. 5A, an array of smaller sized substrates with surface areas down to a few cm², e.g. 2 cm×4 cm and/or various individual shapes may be positioned on a carrier 100 as described herein, particularly a carrier having two or more attachment zones 122. Accordingly, according to some implementations, the carrier can be configured for supporting two or more substrates. Typically, each of the two or more attachment zones 122 may include a plurality of filaments as described herein which are arranged such that a permeable or porous configuration as described herein is obtained. Accordingly, each of the two or more attachment zones 122 may include a dry adhesive material as described herein.

In view of the above it is to be understood that embodiments of the carrier as described herein are suitable to be used in a processing system, for instance a vacuum deposition system for depositing material on a substrate held by a carrier as described herein. Accordingly, according to an aspect of the present disclosure, a use of the carrier according to any embodiments described herein in a processing system, particularly in a vacuum deposition system for depositing material on a substrate, is provided.

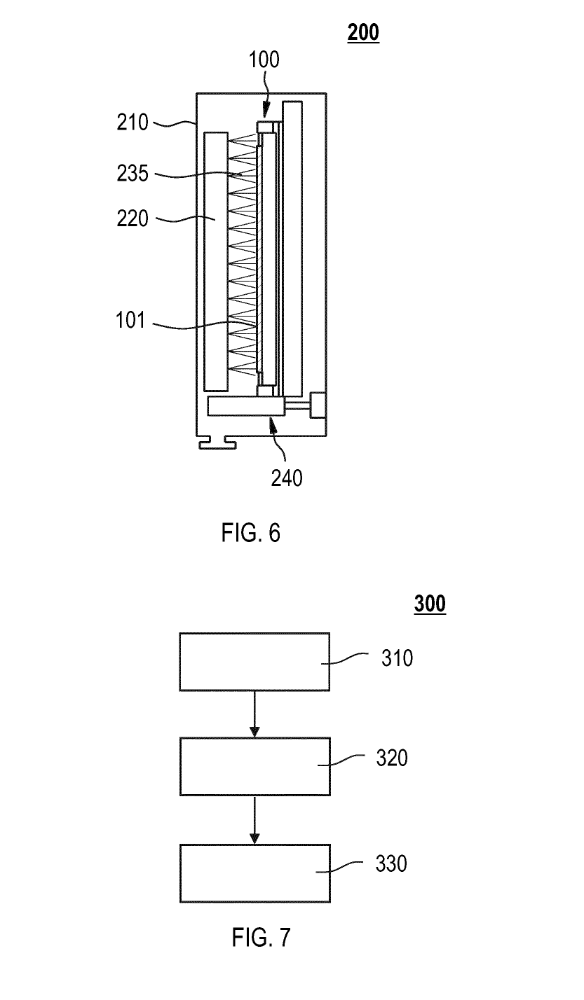

With exemplary reference to FIG. 6 a processing system 200 according to embodiments of the present disclosure are described. The processing system includes a processing chamber 210; a processing device 220; and a carrier 100 according to any embodiments described herein. In particular, the processing chamber 210 may be a vacuum processing chamber, such as a deposition chamber adapted for a vacuum deposition process. For instance, the deposition process can be a PVD or CVD process. Typically, the carrier 100 with the substrate 101 positioned thereon is provided in processing chamber 210 for substrate processing. In particular, the carrier 100 can be configured according to any embodiments described herein. Further, as exemplarily shown in FIG. 6, the processing system 200 may include a transportation device 240 configured for transporting a carrier 100 according to embodiments described herein. Further, the processing system 200 can include a gas supply unit 250 configured for providing a gas into the one or more conduits 115 of the carrier 100 as described herein, such that a temperature of the substrate held by the carrier can be controlled. In particular, the gas supply unit 250 of the processing system 200 is beneficial for providing the possibility of cooling the substrate during substrate processing as described herein.

According to embodiments, which can be combined with other embodiments described herein, the processing device 220 may be a material deposition source which can be provided in the processing chamber 210 facing the side of the substrate 101 to be processed, e.g. coated. As exemplarily indicated in FIG. 6, the material deposition source can provide deposition material 235 to be deposited on the substrate 101. For instance, the deposition material source can be a target with deposition material thereon or any other arrangement allowing material to be released for deposition on the substrate. In some implementations, the material deposition source can be a rotatable target. According to some embodiments described herein, the material deposition source can be movable in order to position and/or replace the material deposition source. According to other embodiments described herein, the deposition material source can be a planar target.

According to some embodiments described herein, which can be combined with other embodiments described herein, the deposition material 235 can be chosen according to the deposition process and the later application of the coated substrate. For instance, the deposition material 335 of the material deposition source can be a material selected from the group consisting of: A metal, such as aluminum, molybdenum, titanium, copper, or the like, silicon, indium tin oxide, and other transparent conductive oxides. Oxide-, nitride- or carbide-layers, which can include such materials, can be deposited by providing the material from the material deposition source or by reactive deposition, i.e. the material from the material deposition source can react with elements like oxygen, nitride, or carbon from a processing gas.

FIG. 7 shows a flow chart illustrating a method 300 for controlling a temperature of a substrate according to embodiments described herein. According to embodiments, which can be combined with any other embodiments described herein, the method 300 includes providing 310 a carrier according to any embodiments described herein; supplying 320 a gas through the one or more conduits into the adhesive arrangement; and providing 330 the gas to a backside of the substrate attached to the adhesive arrangement.

According to embodiments, which can be combined with any other embodiments described herein, supplying 320 a gas through the one or more conduits into the adhesive arrangement includes distributing the gas in the adhesive arrangement, particularly in a substantially uniform manner. Accordingly, beneficially a substantially uniform or homogeneous thermal control of the substrate held by the adhesive arrangement of the carrier as described herein can be provided.

According to embodiments, which can be combined with any other embodiments described herein, providing 330 the gas to a backside of the substrate attached to the adhesive arrangement includes providing a gas flow along the backside of the substrate, i.e. a gas convection, for providing a heat transfer from the substrate to the gas. Accordingly, beneficially a substantially uniform or homogeneous thermal control of the substrate held by the adhesive arrangement of the carrier as described herein can be provided.

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A carrier for holding a substrate, comprising:
a carrier body having a first surface; and
an adhesive arrangement provided on the first surface, wherein the carrier body comprises one or more conduits configured for providing a gas into the adhesive arrangement.

2. The carrier according to claim 1, wherein the adhesive arrangement is configured to be permeable to gas.

3. The carrier according to claim 1, wherein the adhesive arrangement comprises a plurality of filaments.

4. The carrier according to claim 1, wherein the adhesive arrangement comprises a dry adhesive material configured for attaching the substrate to the carrier body.

5. The carrier according to claim 4, wherein the dry adhesive material is a synthetic setae material.

6. The carrier according to claim 1, wherein the one or more conduits are configured to extend from a second surface of the carrier body to the first surface of the carrier body, wherein the second surface is opposed to the first surface, or wherein the one or more conduits are connected to a gas supply conduit configured to guide the gas through
the carrier body to the one or more conduits.

7. The carrier according to claim 1, wherein the adhesive arrangement is configured to have an attachment area which corresponds to at least 75% of a backside surface of the substrate.

8. The carrier according to claim 1, wherein the one or more conduits comprise a plurality of conduits which are distributed in the carrier body.

9. The carrier according to claim 1, wherein the adhesive arrangement is configured to have two or more attachment zones.

10. The carrier according to claim 9, wherein the one or more conduits are configured such that each of the two or more attachment zones can be provided with gas.

11. Use of a carrier for holding a substrate in a vacuum deposition system for depositing material on a substrate, the carrier comprising:
a carrier body having a first surface; and
an adhesive arrangement provided on the first surface, wherein the carrier body comprises one or more conduits configured for providing a gas into the adhesive arrangement.

12. A processing system comprising:
a processing chamber;
a processing device; and
a carrier for holding a substrate, the carrier comprising:
a carrier body having a first surface, and
an adhesive arrangement provided on the first surface, wherein the carrier body comprises one or more conduits configured for providing a gas into the adhesive arrangement.

13. A method for controlling a temperature of a substrate, comprising:
providing a carrier for holding a substrate, the carrier comprising:
a carrier body having a first surface, and
an adhesive arrangement provided on the first surface, wherein the carrier body comprises one or more conduits configured for providing a gas into the adhesive arrangement;
supplying a gas through the one or more conduits into the adhesive arrangement; and
providing the gas to a backside of the substrate attached to the adhesive arrangement.

14. The method according to claim 13, wherein supplying a gas through the one or more conduits into the adhesive arrangement comprises distributing the gas in the adhesive arrangement.

15. The method according to claim 13, wherein providing the gas to the backside of the substrate attached to the adhesive arrangement comprises providing a gas flow along the backside of the substrate for providing a heat transfer from the substrate to the gas.

16. The carrier according to claim 4, wherein the dry adhesive material is a Gecko adhesive.

17. The carrier according to claim 4, wherein the one or more conduits are configured to extend from a second surface of the carrier body to the first surface of the carrier body, wherein the second surface is opposed to the first surface, or wherein the one or more conduits are connected to a gas supply conduit configured to guide the gas through the carrier body to the one or more conduits.

18. The carrier according to claim 4, wherein the adhesive arrangement is configured to have an attachment area which corresponds to at least 75% of a backside surface of the substrate.

19. The carrier according to claim 2, wherein the one or more conduits comprise a plurality of conduits which are distributed in the carrier body.

20. The carrier according to claim 2, wherein the one or more conduits comprise a plurality of conduits which are distributed in a regular manner in the carrier body.
